(19) United States
(12) Patent Application Publication
(10) Pub. No.: US 2025/0113717 A1
(43) Pub. Date: Apr. 3, 2025

(54) DISPLAY DEVICE FOR DISPLAYING INFORMATION, DISPLAY SYSTEM COMPRISING THE DISPLAY DEVICE, METHOD FOR CHANGING THE TRANSPARENCY WHILE DISPLAYING INFORMATION AND A METHOD FOR PRODUCING THE DISPLAY DEVICE OR THE DISPLAY SYSTEM

(71) Applicant: Continental Automotive Technologies GmbH, Hannover (DE)

(72) Inventors: Junn Yaw Ong, Singapore (SG); Yew Chye Leonard Shen, Singapore (SG); Wen Yao Jackson Chan, Singapore (SG)

(73) Assignee: Continental Automotive Technologies GmbH, Hannover (DE)

(21) Appl. No.: 18/832,589

(22) PCT Filed: Nov. 3, 2022
(86) PCT No.: PCT/EP2022/080610

§ 371 Date: Jul. 24, 2024

(30) Foreign Application Priority Data
Jan. 26, 2022 (GB) 2200969.0

(51) Int. Cl. H10K 59/50; C07F 7/24

(52) U.S. Cl. CPC H10K 59/50; C07F 7/24

(57) ABSTRACT

The disclosure relates to a display device for displaying information, comprising at least one layer unit operable to change the quantity of light rays to pass through the layer unit, at least one display unit configured to display an image, wherein the at least one layer unit comprises or consists, mainly or fully, of at least one metal halide perovskite. The disclosure also relates to a display system comprising the display device as well as a method for changing the transparency while displaying information and a method for producing the display device or the display system.

### CROSS REFERENCE TO RELATED APPLICATIONS

This US patent application claims the benefit of PCT patent application No. PCT/EP2022/080610, filed Nov. 3, 2022, which claims the benefit of patent application GB 2200969.0, filed Jan. 26, 2022, both of which are hereby incorporated by reference.

### TECHNICAL FIELD

The disclosure relates to a display device for displaying information. The disclosure also relates to a display system comprising the display device as well as a method for changing the transparency while displaying information and a method for producing the display device or the display system.

### BACKGROUND

Display devices are used for the displaying of information. There is a wide variety of display devices, such as see-through transparent display devices. An example of a transparent display device is an organic light emitting diode (OLED) display, which has been incorporated into various consumer products such as televisions and windows. An example of a consumer product with OLED displays incorporated is a vehicle, with an increasing number of displays being integrated into the interior of modem vehicles. For example, the side windows of a vehicle may be replaced with a hybrid comprising a glass window and a transparent OLED display capable of displaying information.

In general, the contrast ratio of a transparent display device is dependent on the amount of light passing through the transparent display device. The lower the amount of light passing through the transparent display device, the better the contrast ratio, and vice versa. Therefore, existing transparent display devices do not have good contrast ratio, especially in bright environments due to the large amount of light passing through the transparent display device. Furthermore, display devices consume high levels of energy, which increases fuel or energy consumption when incorporated into consumer products.

Transparent layers or surfaces, such as glass, have been adapted to serve additional functions. An example is photochromic glass usually comprising silver halides which is used to provide shade due to its ability to turn dark when exposed to light of sufficient frequency and revert to its clear state in the absence of activating light. Another example is photovoltaic glass comprising an almost transparent solar cell thin film which is used to convert solar energy into usable electrical energy due to its ability to convert light into electricity.

Neither photochromic glass nor photovoltaic glass solve the various shortcomings of transparent display devices. Photochromic glass may improve the contrast ratio of the transparent display device but does not assist in reducing fuel or energy consumption of the display device. On the other hand, although photochromic glass generates electricity which may reduce fuel or energy consumption of the display device, the solar cell energy conversion of most photochromic glass is low and photochromic glass does not improve the contrast ratio of the display device as photochromic glass is transparent.

### SUMMARY

The technical problems to be solved by the present disclosure are to provide a display device with good contrast ratio and reduced energy consumption.

To solve the above technical problems, the present disclosure provides a display device for displaying information, comprising at least one layer unit operable to change the quantity of light rays to pass through the layer unit, and at least one display unit configured to display an image, wherein the at least one layer unit comprises or consists, mainly or fully, of at least one metal halide perovskite.

The incorporation of at least one layer unit comprising metal halide perovskite to change the quantity of light rays passing through the layer unit overcomes the technical problems in existing transparent display devices. Metal halide perovskite has a broad light absorption range. In particular, metal halide perovskite exhibits high absorbance and low transmission of light rays in the ultraviolet (UV) light energy range, thus metal halide perovskite turns darker under bright environments. Therefore, metal halide perovskite reduces the amount or quantity of light passing through the at least one layer unit and consequently through the at least one display unit, thereby increasing the overall performance of the transparent display device by improving the contrast ratio. In addition, the darkened state of the metal halide perovskite of the layer unit also provides shade to occupants of vehicles when incorporated into the windows of a vehicle or shade to occupants of buildings when incorporated into the windows of a building.

A preferred display device of the present disclosure is a display device as described above or as described above as being preferred, wherein the at least one metal halide perovskite is a metal halide perovskite having a formula of A_{X}B_{Y}C_{Z} wherein A is any suitable anion, preferably methylamine (MA), formamidine (FA), and/or caesium (Cs); B is a metal having the valency of 2+, preferably lead (Pb), tin (Sn), or a combination thereof, and C is a halogenide, preferably iodide; wherein x, y, z can be any rational number between 1 and 10; wherein preferably: A is methylamine (MA), or formamidine (FA); B is lead (Pb); and C is an iodide; and wherein x, y, z can be any integer between 0 and 10; wherein even more preferably the at least one metal halide perovskite has the formula (CH₃)H₃NPbI₃ or FA₂Pb₁I₄.

The above-described aspect of the present disclosure has the advantage that at least one layer unit with metal halide perovskites comprising lead (Pb) and/or iodide are more stable and durable than layer units with metal halide perovskites comprising other metals and/or other halides. Moreover, layer units with metal halide perovskites comprising methylamine (MA) or formamidine (FA) can be produced more efficiently, meaning, for example, with less waste and less toxins than layer units with other metal halide perovskites.

A preferred display device of the present disclosure is a display device as described above or as described above as being preferred, wherein one surface of the layer unit, also called the display surface of the layer unit, and one surface of the display unit, also called the layer surface of the display unit, are fully or partially in contact with one another, wherein said two surfaces preferably form an interface between the layer unit and the display unit.

The above-described aspect of the present disclosure has the advantage that such display devices have a better contrast ratio.

A particularly preferred display device of the present disclosure is a display device as described above or as described above as being preferred, wherein the display device comprises either only the layer unit and the display unit and no further unit; or one or two or three primary additional layers on top of the layer unit; and/or on top of the display unit; and/or between the layer unit and the display unit; and optionally secondary additional layers, wherein the secondary additional layers are not in contact with the layer unit or the display unit but only with the primary additional layers or other secondary additional layers, wherein preferably all primary additional layers and secondary additional layers have a transparency in the range from 50 to 100% for light rays having a wavelength in the range from 350 nm to 800 nm, more preferably a transparency in the range from 70 to 99.9% for light rays having a wavelength in the range from 350 nm to 800 nm, even more preferably in the range from 80 to 99% for light rays having a wavelength in the range from 350 nm to 800 nm.

The above-described aspect of the present disclosure has the advantage that the display device with one or two or three primary additional layers and optional secondary additional layers would be more durable as the one or two or three primary additional layers and optional secondary additional layers protect the display unit and the layer unit.

For the purpose of the present disclosure, the term “transparency” refers to the amount or quantity of light rays transmitted through a certain material. The transparency of a material may be measured by photometer of the company “TechnoTeam” with the model “LMK 5” in the measuring mode “luminance measurement”, or through any other known method for determining a percentage or proportion of light rays transmitted through a material.

An even more particularly preferred display device of the present disclosure is a display device as described above or as described above as being preferred or as described above as being particularly preferred, wherein the display device comprises two primary additional layers consisting of a transparent, non-crystalline and amorphous solid, preferably glass, wherein preferably said transparency of the transparent, non-crystalline and amorphous solid is a transparency in the range from 50 to 100% for light rays having a wavelength in the range from 350 nm to 800 nm, more preferably a transparency in the range from 70 to 99.9% for light rays having a wavelength in the range from 350 nm to 800 nm, even more preferably in the range from 80 to 99% for light rays having a wavelength in the range from 350 nm to 800 nm.

The above-described aspect of the present disclosure has the advantage that the two primary additional layers consisting of a transparent, non-crystalline and amorphous solid would allow light rays to pass through one or both of the two primary additional layers and fall onto the layer unit and thus cause the layer unit to change the quantity of light rays passing through the layer unit.

A preferred display device of the present disclosure is a display device as described above or as described above as being preferred or as described as above as being particularly preferred or as described above as being even more particularly preferred, wherein the layer unit is configured to generate a current and/or voltage when light rays, non-generated light rays and/or generated light rays pass through the layer unit.

The above-described aspect of the present disclosure has the advantage that the current and/or voltage generated by the layer unit may be used by the display device (or other electronic devices connected to the display device) and thus decrease overall energy consumption of the display device or any other electronic device connected to the display device. Metal halide perovskite has a wide electronic band structure such that metal halide perovskite is able to generate electricity similar to a solar cell with a power conversion efficiency of >25%. This electricity generated may be harvested and utilized to power the display device, or any other systems electrically connected to the display device that utilize electricity. Therefore, metal halide perovskite reduces fuel or energy consumption of the display device by acting as an additional energy source for energy consuming display devices. This also leads to cost savings as the resulting display device is multifunctional.

A preferred display device of the present disclosure is a display device as described above or as described above as being preferred or as described above as being particularly preferred or as described above as being even more particularly preferred, wherein the layer unit is configured to change the quantity of light rays to pass through the layer unit in a first direction when the wavelength and/or quantity of the light rays passing through the layer unit in a different direction, preferably a different direction perpendicular to the first direction, non-generated light rays passing through the layer unit and/or generated light rays passing through the layer unit is changed.

The above-described aspect of the present invention has the advantage that the transparency of the layer unit may be changed or adjusted independently from the sun rays or other non-generated light rays.

A preferred display device of the present disclosure is a display device as described above or as described above as being preferred or as described above as being particularly preferred or as described above as being even more particularly preferred, wherein the display unit is an organic light-emitting diode (OLED) display.

The above-described aspect of the present disclosure has the advantage that OLED displays are flexible, provide images with better colour and contrast, and do not require an external backlight to function.

A particularly preferred display device of the present disclosure is a display device as described above or as described above as being preferred or as described above as being particularly preferred or as described above as being even more particularly preferred, comprising at least one layer unit operable to change the quantity of light rays to pass through the layer unit; at least one display unit configured to display an image, wherein the at least one layer unit comprises or consists, mainly or fully, of at least one metal halide perovskite, and wherein the display unit is an OLED display; the at least one metal halide perovskite has the formula (CH₃)H₃NPbI₃ or FA₂Pb₁I₄; one surface of the layer unit and one surface of the display unit are fully in contact with one another, wherein said two surfaces form an interface between the layer unit and the display unit; the display device comprises either only the layer unit and the display unit and no further unit; or two primary additional layers, one on top of the layer unit; and one on top of the display unit, wherein the two primary additional layers consist of a transparent, non-crystalline and amorphous solid, preferably glass, wherein preferably said transparency of the transparent, non-crystalline and amorphous solid is a transparency in the range from 80 to 99% for light rays having a wavelength in the range from 350 nm to 800 nm.

The above-described advantageous aspects of a display device of the disclosure also hold for all aspects of a below described display system of the disclosure. All below described advantageous aspects of a display system of the disclosure also hold for all aspects of an above-described display device of the disclosure.

The disclosure also relates to a display system for displaying information for a driver of a vehicle, comprising one or more display devices according to the invention; a control unit configured to control the information displayed on the one or more display devices; and optionally, at least one light generating unit configured to send generated light rays with a determined wavelength and/or intensity to at least one specific layer unit, several layer units or each layer unit of the one or more display devices.

A preferred display system of the present disclosure is a display system as described above or as described above as being preferred, wherein the display system further comprises a light generating unit operable to generate light rays, wherein the light generating unit is configured to generate light rays of different wavelength and/or of different intensity and to send a determined intensity of generated light rays with or without a determined wavelength to one, several or each layer unit of the one or more display devices so that the quantity of light rays passing through the layer unit is changed.

A preferred display system of the present disclosure is a display system as described above or as described above as being preferred, wherein the control unit is additionally configured to control the wavelength and/or the intensity of the generated light rays generated by the light generating unit to the or each layer unit of the one or more display devices.

The two previously described aspects of the present disclosure have the advantage that transparency of the layer unit may be changed independently from the sun rays or other non-generated light rays by using a light generating unit.

The above-described advantageous aspects of a display device of the disclosure and of the above-described display system of the invention also hold for all aspects of a below described method for changing the transparency while displaying information. All below described advantageous aspects of a method for changing the transparency while displaying information also hold for all aspects of an above-described display device of the disclosure or an above-described display system of the disclosure.

The disclosure also relates to a method for changing the transparency while displaying information, preferably for a driver in a vehicle, comprising the steps of sending instructions, by a control unit, to one or more display devices according to the present invention so that images are displayed on at least one of the one or more display devices, wherein the control unit is preferably a control unit in a display system according to the present disclosure, and simultaneously or sequentially displaying such images on at least one of the one or more display devices while the quantity of non-generated light rays passing through the layer unit is changed.

A preferred method of the present disclosure is a method as described above or as described above as being preferred, wherein the step of changing the quantity of light rays passing through the layer unit comprises sending instructions, by a or the control unit, to a light generating unit so that the light generating unit sends generated light rays to a specific, several or each layer unit of one or more display devices as described above or as described above as being preferred or as described above as being particularly preferred so that the quantity of non-generated light rays passing through the layer unit changes.

The above-described aspect of the present disclosure has the advantage that the light rays generated by the light generating unit may fall on the layer unit and further change the quantity of non-generated light rays (e.g., sunlight) passing through the layer unit, thus providing better contrast of the display unit under brighter environments.

A preferred method of the present disclosure is a method as described above or as described above as being preferred, wherein the method additionally comprises generating an electric current and/or voltage from the layer unit when light rays pass through said layer unit; and optionally use the in generated electric current and/or voltage, preferably by the display unit, the light generating unit and/or the control unit.

The above-described aspect of the present disclosure has the advantage that the energy generated may be harvested, thus reducing the overall energy consumption of the display device and/or display system.

The above-described advantageous aspects of a display device of the disclosure and of the above-described display system of the disclosure as well as for the above-described method for changing the transparency while displaying information also hold for all aspects of a below described method for producing a display device according to the present disclosure and/or a display system according to the present disclosure. All below described advantageous aspects of a method for producing a display device according to the present disclosure and/or a display system according to the present disclosure also hold for all aspects of an above-described display device of the disclosure or an above-described display system of the disclosure as well as the above-described method for changing the transparency while displaying information.

The disclosure also relates to a method for producing a display device according to the present disclosure and/or a display system according to the present disclosure, comprising the steps of providing or producing a display unit, optionally dissolving a salt comprising at least one ion of the at least one metal halide perovskite as defined in any of the display devices as described above or as described above as being preferred or as described above as being particularly preferred or as described above as being even more particularly preferred; producing a layer unit onto one surface of the display unit, preferably by using the dissolved at least one ion of the at least one metal halide perovskite dissolved, so that a display device as described above or as described above as being preferred or as described above as being particularly preferred or as described above as being even more particularly preferred results; and optionally providing and configuring a light generating unit to send generated light rays to the layer unit of the display device; and/or a control unit to control the information displayed on the display unit of the one or more display devices so that a display system as described above or as described above as being preferred or as described above as being particularly preferred results.

### BRIEF DESCRIPTION OF THE DRAWINGS

These and other features, aspects, and advantages will become better understood with regard to the following description, appended claims, and accompanying drawings where:

FIG. 1 is a schematic illustration of a cross-sectional view of a display device for displaying information, in accordance with embodiments of the present disclosure;

FIG. 2 is a schematic illustration of a cross-sectional view of a display device further comprising primary additional layers, in accordance with embodiments of the present disclosure;

FIG. 3 is a schematic illustration of a cross-sectional view of a display device further comprising primary additional layers and secondary additional layers, in accordance with embodiments of the present disclosure;

FIG. 4 is a schematic illustration of a layer unit of a display device configured to generate a current and/or voltage, in accordance with embodiments of the present disclosure;

FIG. 5 is a schematic illustration of a front perspective view of a layer unit of a display device, in accordance with embodiments of the present disclosure;

FIG. 6 is a schematic illustration of a display system for displaying information, in accordance with embodiments of the present disclosure;

FIG. 7 is a flowchart showing a method for changing the transparency of a display device while displaying information, in accordance with embodiments of the present disclosure; and

FIG. 8 is a flowchart showing a method for producing a display system, in accordance with embodiments of the present disclosure.

In the drawings, like parts are denoted by like reference numerals.

It should be appreciated by those skilled in the art that any block diagrams herein represent conceptual views of illustrative systems embodying the principles of the present subject matter. Similarly, it will be appreciated that any flow charts, flow diagrams, state transition diagrams, pseudo code, and the like represent various processes which may be substantially represented in computer readable medium and executed by a computer or processor, whether or not such computer or processor is explicitly shown.

### DETAILED DESCRIPTION

In the summary above, in this description, in the claims below, and in the accompanying drawings, reference is made to particular features (including method steps) of the disclosure. It is to be understood that the disclosure of the invention in this specification includes all possible combinations of such particular features. For example, where a particular feature is disclosed in the context of a particular aspect or embodiment of the invention, or a particular claim, that feature may also be used, to the extent possible, in combination with and/or in the context of other particular aspects and embodiments of the disclosure, and in the inventions generally.

In the present document, the word “exemplary” is used herein to mean “serving as an example, instance, or illustration.” Any embodiment or implementation of the present subject matter described herein as “exemplary” is not necessarily be construed as preferred or advantageous over other embodiments.

While the disclosure is susceptible to various modifications and alternative forms, specific embodiment thereof has been shown by way of example in the drawings and will be described in detail below. It should be understood, however that it is not intended to limit the disclosure to the forms disclosed, but on the contrary, the disclosure is to cover all modifications, equivalents, and alternative falling within the scope of the disclosure.

Disclosed herein is a display device for displaying information, a display system comprising the display device, method for changing the transparency while displaying information and a method for producing the display device or the display system. In some embodiments, the display device or display system may be a standalone device similar to a television. In some embodiments, one or more of the display device or device system may be configured to display information. In some embodiments, one or more of the display device or display system may be installed within a vehicle and configured to display information. In some embodiments, one or more of the display device or display system may be configured to display information for a driver of a vehicle. In some embodiments, one or more of the display device or display system may be installed on or replace one or more windows on a vehicle. In some embodiments, one or more of the display device or display system may be installed on or replace one or more windows of any structure, including buildings.

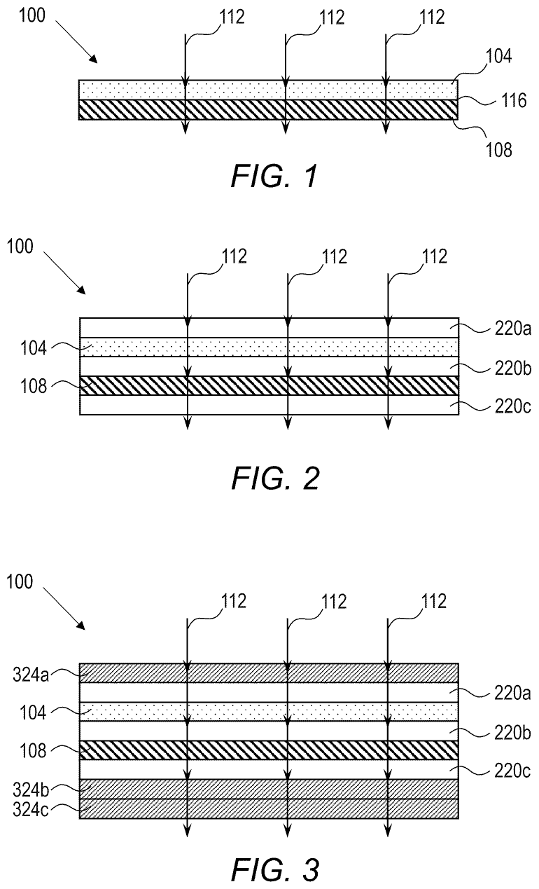

FIG. 1 is a schematic illustration of a cross-sectional view of a display device for displaying information, in accordance with embodiments of the present disclosure. Display device 100 may be configured to display information, images, and/or videos. In some embodiments, display device 100 may comprise at least one layer unit 104 and at least one display unit 108, the at least one layer unit 104 and at least one display unit 108 arranged parallel to each other in any order. For example, where there are two or more layer units 104, the two or more layer units 104 may be arranged against each other or the at least one display unit 108 may be sandwiched between the two or more layer units 104.

According to some embodiments of the present disclosure, the at least one layer unit 104 may be operable to change the quantity of light rays 112 to pass through the at least one layer unit 104. Light rays 112 may pass through layer unit 104 perpendicular to layer unit 104, or at any other angles of incidence. In some embodiments, light rays 112 may be within the ultraviolet (UV) and/or visible light spectrum range. Preferably, light rays 112 have a wavelength of between 350 nm and 800 nm. In some embodiments, the at least one display unit 108 may be configured to display information, such as images, text and/or videos. In some embodiments, the display unit 108 may be an organic light-emitting diode (OLED) display which is flexible and does not require a backlight to operate, although other types of display units may be employed.

According to some embodiments of the present disclosure, the at least one layer unit 104 may comprise or consist of, mainly or fully, of at least one metal halide perovskite. Metal halide perovskite has a broad light absorption range and absorbs light of various wavelengths. In particular, metal halide perovskite has exhibits high absorbance and low transmission of light rays in the ultraviolet (UV) light energy range. The stronger or the higher the intensity of the light or light rays that metal halide perovskite is exposed to, the darker metal halide perovskite becomes and the lower the amount, quantity, or intensity of light or light rays transmitted by or through the metal halide perovskite. Thus, metal halide perovskite changes the quantity, amount or intensity of light rays passing through the layer unit 104 by becoming darker and absorbing light proportional to the amount of light it is exposed to. In some embodiments, the at least one layer unit 104 may comprise a combination of two or more metal halide perovskites. In some embodiments, the at least one metal halide perovskite may be a metal halide perovskite having a chemical formula of A_{X}B_{Y}C_{Z} wherein A is any suitable anion, B is a metal having the valency of 2+, C is a halogenide, and wherein x, y and z may be any rational number between 1 and 10. Preferably, A is methylamine (MA), formamidine (FA), and/or caesium (Cs). More preferably, A is methylamine (MA), or formamidine (FA) as layer units 104 with metal halide perovskites comprising MA or FA can be produced more efficiently, meaning, for example, with less waste and less toxins than layer units with other metal halide perovskites. Preferably, B is lead (Pb), tin (Sn), or a combination thereof. More preferably, B is lead (Pb) which is more stable. Preferably, C is iodide, which is more stable than other halides and would result in a more durable layer unit 104. Preferably, x, y and z are any integer between 1 and 10. Examples of preferred metal halide perovskites include (CH₃)H₃NPbI₃ or FA₂Pb₁I₄. In some embodiments, the metal halide perovskite of layer unit 104 may be a thin film with methylamine (CH₃NH₂) vapour as a solvent.

According to some embodiments of the present disclosure, layer unit 104 and display unit 108 may be in contact with each other, such that one surface of the layer unit 104, also called the display surface of the layer unit 104, and one surface of the display unit 108, also called the layer surface of the display unit 108, are fully or partially in contact with one another, wherein said two surfaces preferably form an interface 116 between the layer unit 104 and the display unit 108. In some embodiments, layer unit 104 comprising or consisting at least one metal halide perovskite may be deposited directly onto a surface of display unit 108, also known as the layer surface of display unit 108. In some embodiments, layer unit 104 comprising or consisting at least one metal halide perovskite may be deposited onto a film before adherence to the layer surface of display unit 108. Layer unit 104 comprising or consisting at least one metal halide perovskite may be deposited onto film using any known methods, including single-step solution deposition, two-step solution deposition, two-step hybrid deposition, and thermal vapor deposition. In some embodiments, the film may comprise poly(methyl methacrylate) (PMMA) or polycarbonate (PC). In some embodiments, layer unit 104 comprising or consisting at least one metal halide perovskite may have a thickness of around 500 nm.

FIG. 2 is a schematic illustration of a cross-sectional view of a display device further comprising primary additional layers, in accordance with embodiments of the present disclosure. In some embodiments, display device 100 may comprise only the layer unit 104 and the display unit 108 and no further unit, as illustrated in FIG. 1. In some embodiments, display device 100 may further comprise one or more primary additional layers 220. Primary additional layers 220 may be layers with a transparency for light rays 112. The degree of transparency to light rays 112 may be determined by using a photometer of the company “TechnoTeam” with the model “LMK 5” in the measuring mode “luminance measurement”, or any other machine that is able to measure the percentage or proportion of light rays 112 transmitted through a certain material. In embodiments with two or more primary additional layers 220, each of the primary additional layers 220 may have the same or differing transparencies from the other primary additional layers 220. Preferably, primary additional layers 220 have a transparency in the range from 50 to 100% for light rays 112 having a wavelength in the range from 350 nm to 800 nm. More preferably, primary additional layers 220 have a transparency in the range from 70 to 99.9% for light rays 112 having a wavelength in the range from 350 nm to 800 nm. Even more preferably, primary additional layers 220 have a transparency in the range from 80 to 99% for light rays 112 having a wavelength in the range from 350 nm to 800 nm.

According to some embodiments of the present disclosure, there may be one or two or three primary additional layers 220 in various positions relative to layer unit 104 and display unit 108. In some embodiments, there may be a primary additional layer 220a on top of layer unit 104, the primary additional layer 220a positioned against a surface of layer unit 104 distal from display unit 108. In some embodiments, there may be a primary additional layer 220b between layer unit 104 and display unit 108, the primary additional layer 220b sandwiched between layer unit 104 and display unit 108. In some embodiments, there may be a primary additional layer 220c on top of display unit 108, the primary additional layer 220c positioned against a surface of display unit 108 distal from layer unit 104. In some embodiments, display device 100 may further comprise one primary additional layer 220, the primary additional layer 220 selected from primary additional layer 220a, primary additional layer 220b, and primary additional layer 220c. In some embodiments, display device 100 may further comprise two primary additional layers 220, the two primary additional layers 220 selected from primary additional layer 220a, primary additional layer 220b, and primary additional layer 220c. In some embodiments, display device 100 may further comprise primary additional layer 220a, primary additional layer 220b, and primary additional layer 220c.

According to some embodiments of the present disclosure, display device 100 may further comprise two primary additional layers 220, the primary additional layers 220 consisting of a transparent, non-crystalline and amorphous solid. Preferably, the primary additional layers 220 are made of glass. Preferably, the primary additional layers 220 are transparent. Preferably, the primary additional layers 220 comprise a transparent, non-crystalline and amorphous solid with a transparency in the range from 50 to 100% for light rays 112 having a wavelength in the range from 350 nm to 800 nm. More preferably, the primary additional layers 220 comprise a transparent, non-crystalline and amorphous solid with a transparency in the range from 70 to 99.9% for light rays 112 having a wavelength in the range from 350 nm to 800 nm. Even more preferably, the primary additional layers 220 comprise a transparent, non-crystalline and amorphous solid with a transparency in the range from 80 to 99% for light rays 112 having a wavelength in the range from 350 nm to 800 nm.

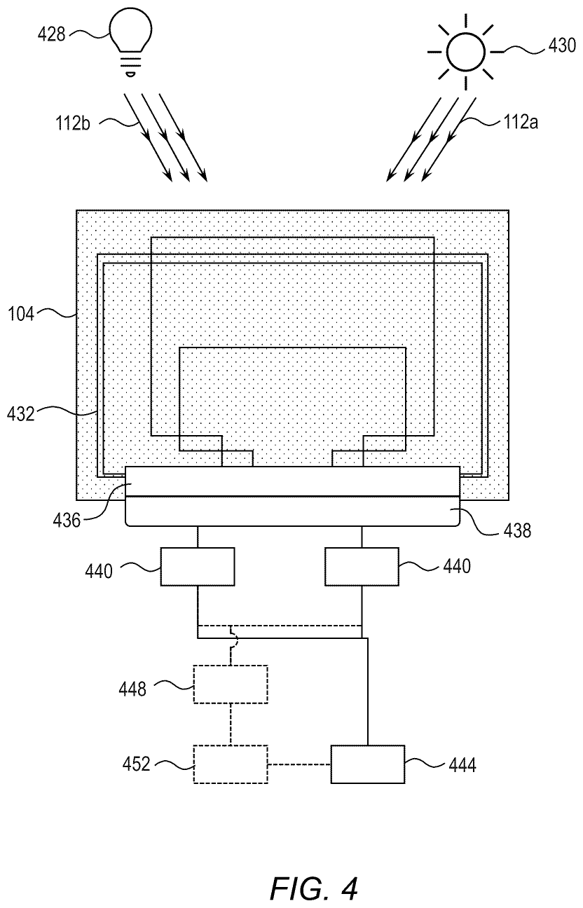

FIG. 3 is a schematic illustration of a cross-sectional view of a display device further comprising primary additional layers and secondary additional layers, in accordance with embodiments of the present disclosure. In some embodiments, display device 100 may further comprise one or more secondary additional layers 324 in addition to primary additional layers 220. In some embodiments, the one or more secondary additional layers 324 may not be in contact with layer unit 104 or display unit 108 but are only in contact with the one or more primary additional layers 220 or other secondary additional layers 324. In some embodiments, there may be a secondary additional layer 324a positioned against a surface of primary additional layer 220a distal from layer unit 104. In some embodiments, there may be a secondary additional layer 324b positioned against a surface of primary additional layer 220c distal from display unit 108. In some embodiments, there may be a secondary additional layer 324c positioned against a surface of secondary additional layer 324b distal from primary additional layer 220c and display unit 108.

According to some embodiments of the present disclosure, the one or more secondary additional layers 324 may be layers which have a transparency for light rays 112. The degree of transparency to light rays 112 may be determined by using a photometer of the company “TechnoTeam” with the model “LMK 5” in the measuring mode “luminance measurement”, or any other machine that is able to measure the percentage of light rays 112 transmitted through a certain material. In some embodiments, secondary additional layers 324 may comprise material that is similar to or the same as primary additional layers 220. In some embodiments, secondary additional layers 324 may comprise material that differs from primary additional layers 220. In embodiments with two or more secondary additional layers 324, each of the secondary additional layers 324 may have the same or differing transparencies from the other secondary additional layers 324. Preferably, secondary additional layers 324 have a transparency in the range from 50 to 100% for light rays 112 having a wavelength in the range from 350 nm to 800 nm. More preferably, secondary additional layers 324 have a transparency in the range from 70 to 99.9% for light rays 112 having a wavelength in the range from 350 nm to 800 nm. Even more preferably, secondary additional layers 324 have a transparency in the range from 80 to 99% for light rays 112 having a wavelength in the range from 350 nm to 800 nm.

FIG. 4 is a schematic illustration of a layer unit of a display device configured to generate a current and/or voltage, in accordance with embodiments of the present disclosure. In some embodiments, layer unit 104 of display device 100 may be configured to generate a current and/or voltage when light rays 112 pass through the layer unit 104. Metal halide perovskite has a wide electronic band structure such that metal halide perovskite is able to generate electricity. This electricity generated may be harvested and utilized to power the display device 100, which decreases overall energy consumption of the display device 100. The electricity generated may also be utilized to power other systems electrically connected to the display device that may utilize electricity.

According to some embodiments, light rays 112 may be any type of light rays from any source, including non-generated light rays 112a such as direct and/or reflected light rays from the sun 430, and generated light rays 112b such as light rays generated by a light generating unit 428. A current and/or voltage may be generated when light rays 112 pass through layer unit 104 in any direction, including in a direction perpendicular to layer unit 104, or in any direction having any angle of incidence relative to layer unit 104.

According to some embodiments of the present disclosure, layer unit 104 may further comprise one or more printed circuits 432 deposited on its surface, the one or more printed circuits 432 configured to harvest electrons generated when the metal halide perovskites of layer unit 104 absorb light from light rays 112. Printed circuit 432 may have any pattern although printed circuit 432 is depicted with an arbitrary pattern in FIG. 4 for illustration purposes. In some embodiments, the one or more printed circuits 432 may comprise fine gold particles. In some embodiments, the one or more printed circuits 432 may be connected to an integrated circuit (IC) chip 436 bonded or mounted on layer unit 104, the IC chip 436 further connected to a connector 438, also known as a flexible printed circuit (FPC). The size and/or dimension of IC chip 436 and connector 438 may vary depending on the intended application of display device 100.

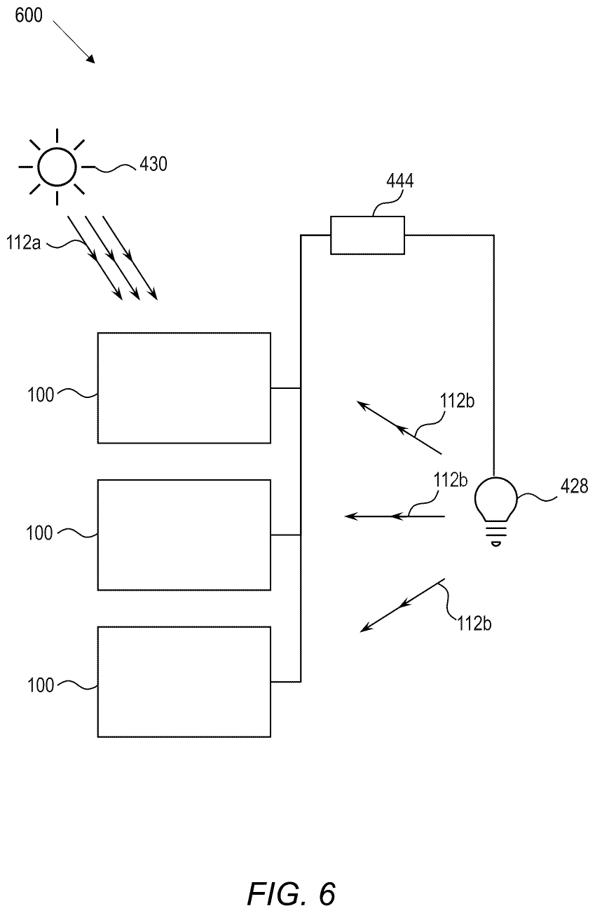

According to some embodiments of the present disclosure, layer unit 104 may be further connected to two electrodes 440, a cathode and an anode, through connector 438. The positions of the two electrodes 440 may vary depending on the intended application of display device 100. In some embodiments, the two electrodes 440 may be electrically connected to one or more control units 444, which may comprise a regulator or distributor. In some embodiments, the one or more control units 444 may utilize or distribute the current and/or voltage generated by the metal halide perovskites of layer unit 104. In some embodiments, the one or more control units 444 may distribute the current and/or voltage to components of display device 100, components of display system 600 (see FIG. 6), or any other electrical systems or subsystems connected to control unit 444. Preferably, the one or more control units 444 may distribute the current and/or voltage generated by the metal halide perovskites of layer unit 104 to display unit 108 and/or light generating unit 428 for usage by the display unit 108 and/or light generating unit 428 (see FIG. 6). In some embodiments, the two electrodes 440 may optionally be electrically connected to a battery charger controller 448, which may be connected to an energy store or battery 452 which is then connected to the one or more control units 444, such that the current and/or voltage generated by the metal halide perovskites of layer unit 104 may be stored in battery 452 for subsequent utilization and/or distribution by the one or more control units 444.

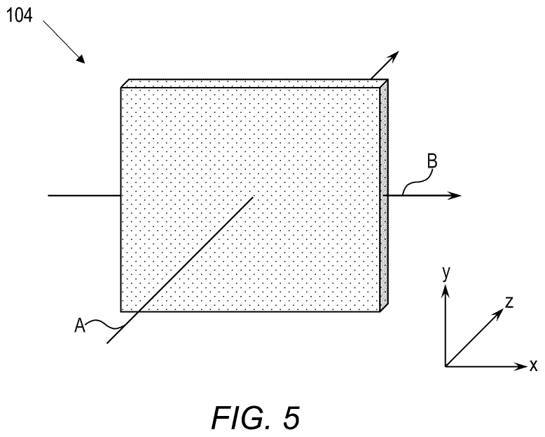

FIG. 5 is a schematic illustration of a front perspective view of a layer unit of a display device, in accordance with embodiments of the present disclosure. Layer unit 104 may change the quantity of light rays 112 passing through the layer unit 104 in a first direction A. First direction A may be any direction in relation to layer unit 104, including a direction perpendicular to layer unit 104. In some embodiments, layer unit 104 may change the quantity of light rays 112 passing through the layer unit 104 in a first direction A in response to a change in wavelength and/or quantity of additional light rays that layer unit 104 is exposed to. The additional light rays increase the amount of light that layer unit 104 is exposed to, causing the metal halide perovskites of layer unit 104 to become darker and consequently reduce the quantity of light rays 112 passing through layer unit 104 in first direction A. The stronger or more intense the additional light rays, the larger the reduction in quantity of light rays 112 passing through layer unit 104 in first direction A. The change in quantity of light rays 112 passing through layer unit 104 may thus be adjusted or altered based on a change in wavelength and/or quantity of additional light rays, and independently from sun rays.

According to some embodiments of the present disclosure, the additional light rays may be light rays 112 passing through layer unit 104 in a second direction B that is a different direction from first direction A. Preferably, second direction B is a direction perpendicular to the first direction A. For example, first direction A may be along the z-axis, while second direction B may be along the x-axis or y-axis. In some embodiments, the additional light rays may be non-generated light rays 112a passing through the layer unit 104, such as direct or reflected sunlight. In some embodiments, the additional light rays may be generated light rays 112b passing through the layer unit 104, the generated light rays 112b generated by light generating unit 428.

FIG. 6 is a schematic illustration of a display system for displaying information, in accordance with embodiments of the present disclosure. Display system 600 for displaying information may comprise one or more display devices 100. In some embodiments, display system 600 may display information for an occupant or driver of a vehicle. In some embodiments, display device 100 of display system 600 may replace windows of the vehicle. The vehicle may be any machine that is used for transporting people or goods, including a car, truck, van, motorcycle, train, or any other vehicle. In some embodiments, display system 600 may display information for an occupant of a building, the display device 100 of display device 600 incorporated into one or more windows of a building. In some embodiments, display system 600 may display information as a standalone system. In some embodiments, display system 600 may further comprise one or more control units 444, the one or more controls unit 444 connected to the one or more display devices 100 and configured to control the information displayed on the display units 108 of the one or more display devices 100. In some embodiments, control unit 444 may be an electronic control unit or an electronic control module, which may be an embedded system in a vehicle that controls one or more electrical systems or subsystems in a vehicle. In some embodiments, control unit 444 may be part of a vehicle central system which acts as a regulator or distributor. In some embodiments, the display of information on the display unit 108 and the distribution of current and/or voltage from layer unit 104 are controlled by the same control unit 444. In some embodiments, the display of information on the display units 108 and the distribution of current and/or voltage from layer unit 104 are controlled by separate or different control units 444. In some embodiments, control unit 444 may be powered by current and/or voltage generated by layer unit 104 of one or more display devices 100 when non-generated light rays 112a from the sun 430 are absorbed by layer unit 104.

According to some embodiments of the present disclosure, display system 600 may further comprise at least one light generating unit 428. Light generating unit 428 may be any device that generates, emits, or otherwise produces light or generated light rays 112b. Light generating unit 428 may be positioned at any location proximate to the one or more display devices 100. The incorporation of light generating unit 428 enables the control, personalisation and/or customisation of the extent to which the at least one layer unit 104 changes the quantity of light rays 112 passing through the layer unit 104. Light generating unit 428 increases the amount of light that layer unit 104 is exposed to, which in turn decreases the quantity of light rays 112 that can pass through layer unit 104. In other words, the incorporation of light generating unit 428 allows a user to increase the contrast of display unit 108 by further increasing the darkness of layer unit 104.

According to some embodiments of the present disclosure, light generating unit 428 may only generate light at a specific wavelength and intensity. In some embodiments, light generating unit 428 may generate light at varying wavelengths and/or varying intensities. In some embodiments, the wavelength and/or intensity of light generated by light generating unit 428 may be determined or controlled by one or more control units 444. In some embodiments, a user may use the one or more control units 444 to determine or control the wavelength and/or intensity of light generated by light generating unit 428. In some embodiments, the determination of light emitting from light generating unit 428, the display of information on the display units 108 and the distribution of current and/or voltage from layer unit 104 are controlled by the same control unit 444. In some embodiments, the determination of light emitting from light generating unit 428, the display of information on the display units 108 and the distribution of current and/or voltage from layer unit 104 are controlled by separate or different control units 444.

According to some embodiments of the present disclosure, the at least one light generating unit 428 may be configured to generate and send generated light rays 112b to the one or more display devices 100. In some embodiments, the generated light rays 112b may be any light rays, without any determined wavelength and/or intensity. In some embodiments, the generated light rays 112b may have a determined wavelength and/or intensity. In some embodiments, the generated light rays 112b may have a determined wavelength without a determined intensity. In some embodiments, the generated light rays 112b may have a determined intensity without a determined wavelength. In some embodiments, the generated light rays 112b may have a determined wavelength and a determined intensity. In some embodiments, the at least one light generating unit 428 may be configured to send generated light rays 112b to a specific layer unit 104 of the one or more display devices 100. In some embodiments, the at least one generating unit 428 may be configured to send generated light rays 112b to several layer units 104 of the one or more display devices 100. In some embodiments, the at least one light generating unit 428 may be configured to send generated light rays 112b to each layer unit 104 of the one or more display devices 100. In some embodiments, the determined wavelength of the light rays 112b may be between 350 and 800 nm. In some embodiments, the determined intensity of the generated light rays 112b may be between 100 and 2000 lux.

According to some embodiments of the present disclosure, the at least one light generating unit 428 may be operable to generate light rays 112b, wherein the light generating unit 428 is configured to generate light rays 112b of different or varying wavelengths and/or of different or varying quantity. In some embodiments, the light generating unit 428 may be configured to send a determined intensity of generated light rays 112b with or without a determined wavelength to one layer unit 104 of the one or more display devices 100. In some embodiments, the light generating unit 428 may be configured to send a determined intensity of generated light rays 112b to several layer units 104 of the one or more display devices 100. In some embodiments, the light generating unit 428 may be configured to send a determined intensity of generated light rays 112b to each layer unit 104 of the one or more display devices 100. In some embodiments, the determined intensity of generated light rays 112b may be between 100 and 2000 lux. In some embodiments, the determined wavelength of generated light rays 112b may be between 350 and 800 nm. In some embodiments, the wavelength and/or intensity of generated light rays 112b may be determined by control unit 444, or a user operating control unit 444.

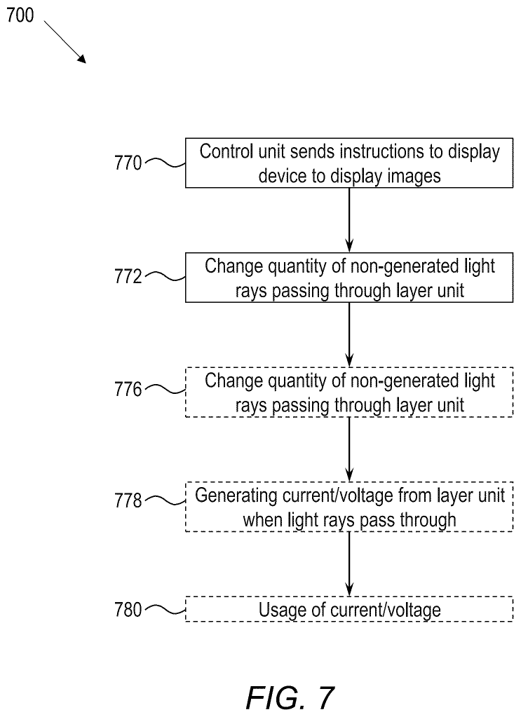

FIG. 7 is a flowchart showing a method for changing the transparency of a display device while displaying information, in accordance with embodiments of the present disclosure. Method 700 for changing the transparency of a display device 100 may commence at step 770, wherein a control unit 444 sends instructions to one or more display devices 100, so that images, text and/or videos are displayed on display unit 108 of the one or more display devices 100. The instructions may be sent through one or more electrical connections between control unit 444 and the one or more display devices 100.

According to some embodiments, method 700 may further comprise step 772, wherein the display of images on the one or more display devices 100 occurs simultaneously or sequentially while the quantity of non-generated light rays 112a passing through layer unit 104 is changed. Preferably, the quantity of non-generated light rays 112a is changed by metal halide perovskite when exposed to non-generated light rays 112a.

According to some embodiments of the present disclosure, in embodiments comprising a light generating unit 428, method 700 may further comprise step 776 wherein changing the quantity of light rays passing through layer unit 104 comprises sending instructions, by a or the control unit 444, to the light generating unit 428 so that the light generating unit 428 sends generated light rays 112b to a specific, several or each layer unit 104 of the one or more display devices 100 so that the quantity of non-generated light rays 112a passing through the layer unit 104 changes. In some embodiments, the control unit 444 used in step 770 is the same as the control unit 444 used in step 776. In other embodiments, the control unit 444 used in step 770 is different from the control unit 444 used in step 776.

According to some embodiments of the present disclosure, method 700 may further comprise step 778 wherein an electric current and/or voltage is generated from layer unit 104 when light rays pass through layer unit 104. Preferably, the current and/or voltage is generated by metal halide perovskites in layer unit 104. Preferably, the current and/or voltage generated is harvested by electrodes 440.

According to some embodiments of the present disclosure, method 700 may further comprise step 780 wherein the electric current and/or voltage generated from layer 104 is used. In some embodiments, the electric current and/or voltage may be directly distributed to a or the control unit 444 and used by the display unit 108, the light generating unit 428, and/or the control unit 444. In some embodiments, the electric current and/or voltage generated may first be stored in an energy store or battery 452 before being distributed to a or the control unit 444 and used by the display unit 108, the light generating unit 428, and/or the control unit 444. In some embodiments, where display device 100 is used in a vehicle, the control unit 444 may further distribute the electric current and/or voltage to other electrical systems or subsystems in the vehicle. In some embodiments, control unit 444 used in steps 770, 776 and 780 are the same. In some embodiments, control unit 444 used in steps 770, 776 and 780 are different.

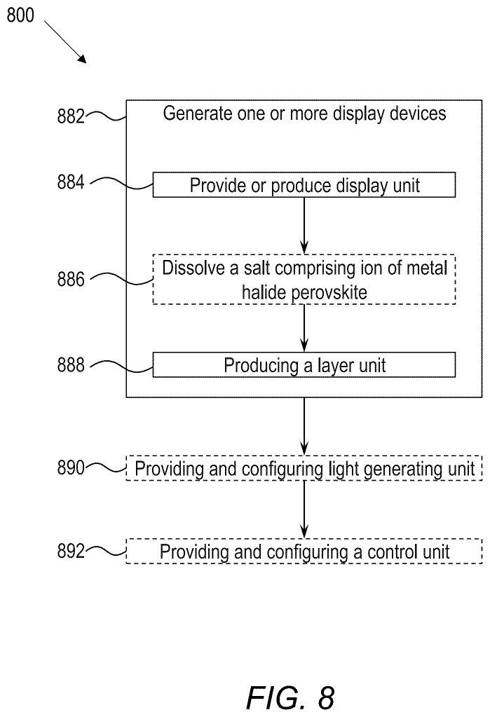

FIG. 8 is a flowchart showing a method for producing a display system, in accordance with embodiments of the present disclosure. Method 800 for producing display system 600 may commence with step 882 wherein one or more display devices 100 are produced. In some embodiments, step 882 may commence with step 884 wherein a display unit 108 is produced or provided. In some embodiments, the display unit 108 is produced. In some embodiments, a commercially available display unit 108 is provided. Examples of commercially available display units include commercially available screens or monitors.

According to some embodiments of the present disclosure, in embodiments where solution deposition is used for metal halide perovskite film fabrication, step 882 of method 800 may optionally continue with step 886, wherein a salt comprising at least one ion of metal halide perovskite is dissolved. The metal halide perovskite may be any metal halide perovskite as previously described in relation to layer unit 104 of display device 100.

According to some embodiments of the present disclosure, step 882 of method 800 may continue with step 888 wherein a layer unit 104 is produced to generate display device 100. In some embodiments, layer unit 104 may be produced or deposited directly onto a surface of display unit 108. In some embodiments where display device 100 further comprises a primary additional layer 220b to be positioned between layer unit 104 and display unit 108, layer unit 104 may be produced or deposited directly onto a surface of the primary additional layer 220b distal from display unit 108 such that the primary additional layer 220b is sandwiched between the produced layer unit 104 and display unit 108. In some embodiments, layer unit 104 may be produced or deposited onto a film before adhesion onto a surface of display unit 108 or a surface of primary additional layer 220b distal from display unit 108. Preferably, layer unit 104 may be produced using the dissolved at least one ion of the at least one metal halide perovskite dissolved in step 886.

According to some embodiments of the present disclosure, after one or more display devices 100 has been produced in step 882, method 800 to generate display system 600 may continue with step 890 wherein a light generating unit 482 is provided and configured to send generated light rays 112b to layer unit 104 of the one or more display devices 100. In some embodiments, the generated light rays 112b may have a wavelength of between 350 and 800 nm. In some embodiments, the generated light rays 112b may have an intensity of between 100 and 2000 lux.

According to some embodiments of the present disclosure, method 800 to generate display system 600 may continue with step 892, wherein a control unit 444 is provided and configured to control the information displayed on display unit 108 of the one or more display devices 100.

The illustrated steps are set out to explain the exemplary embodiments shown, and it should be anticipated that on-going technological development will change the manner in which particular functions are performed. These examples are presented herein for purposes of illustration, and not limitation. Further, the boundaries of the functional building blocks have been arbitrarily defined herein for the convenience of the description. Alternative boundaries may be defined so long as the specified functions and relationships thereof are appropriately performed. Alternatives (including equivalents, extensions, variations, deviations, etc., of those described herein) will be apparent to persons skilled in the relevant art(s) based on the teachings contained herein. Such alternatives fall within the scope and spirit of the disclosed embodiments. The terms “comprises”, “comprising”, “includes” or any other variations thereof, are intended to cover a non-exclusive inclusion, such that a setup, device or method that includes a list of components or steps does not include only those components or steps but may include other components or steps not expressly listed or inherent to such setup or device or method. In other words, one or more elements in a system or apparatus proceeded by “comprises . . . a” does not, without more constraints, preclude the existence of other elements or additional elements in the system or method. It must also be noted that as used herein and in the appended claims, the singular forms “a,” “an,” and “the” include plural references unless the context clearly dictates otherwise.

Finally, the language used in the specification has been principally selected for readability and instructional purposes, and it may not have been selected to delineate or circumscribe the inventive subject matter. It is therefore intended that the scope of the disclosure be limited not by this detailed description, but rather by any claims that issue on an application based here on. Accordingly, the embodiments of the present disclosure are intended to be illustrative, but not limiting, of the scope of the disclosure, which is set forth in the following claims.

1. A display device for displaying information, comprising:
at least one layer unit operable to change a quantity of light rays to pass through the layer unit, and
at least one display unit configured to display an image,
wherein the at least one layer unit comprises at least one metal halide perovskite.

2. The display device according to claim 1, wherein the at least one metal halide perovskite is a metal halide perovskite having a formula of A_{X}B_{Y}C_{Z} wherein:
A is any suitable anion;
B is a metal having a valency of 2+;
C is a halogenide; and
wherein x, y, z is any rational number between 1 and 10.

3. The display device according to claim 1, wherein one surface of the at least one layer unit and one surface of the at least one display unit are fully or partially in contact with one another, wherein said two surfaces form an interface between the at least one layer unit and the at least one display unit.

4. The display device according to claim 1, wherein the display device comprises:
either only the at least one layer unit and the at least one display unit and no further unit; or
one or two or three primary additional layers located
on top of the layer unit and/or
on top of the display unit and/or
between the layer unit and the display unit; and
secondary additional layers, wherein the secondary additional layers are not in contact with the at least one layer unit or the at least one display unit but only with the primary additional layers or other secondary additional layers, wherein all primary additional layers and secondary additional layers have a transparency in the range from 50 to 100% for light rays having a wavelength in the range from 350 nm to 800 nm, more preferably a transparency in the range from 70 to 99.9% for light rays having a wavelength in the range from 350 nm to 800 nm, even more preferably in the range from 80 to 99% for light rays having a wavelength in the range from 350 nm to 800 nm.

5. The display device according to claim 4, wherein the display device comprises two primary additional layers consisting of a transparent, non-crystalline and amorphous solid, wherein said transparency of the transparent, non-crystalline and amorphous solid is a transparency in the range from 50 to 100% for light rays having a wavelength in the range from 350 nm to 800 nm, more preferably a transparency in the range from 70 to 99.9% for light rays having a wavelength in the range from 350 nm to 800 nm, even more preferably in the range from 80 to 99% for light rays having a wavelength in the range from 350 nm to 800 nm.

6. The display device claim 1, wherein the layer unit is configured:
to generate a current and/or voltage when light rays, non-generated light rays and/or generated light rays pass through the at least one layer unit;
and/or
to change the quantity of light rays to pass through the layer unit in a first direction when the wavelength and/or quantity of
the light rays passing through the layer unit in a different direction perpendicular to the first direction;
non-generated light rays passing through the layer unit; and/or
generated light rays passing through the layer unit is changed.

7. The display device according to claim 1, wherein the at least one display unit is an organic light-emitting diode (OLED) display.

8. A display system for displaying information for a driver of a vehicle, comprising:
one or more display devices comprising:
at least one layer unit operable to change the quantity of light rays to pass through the layer unit, and
at least one display unit configured to display an image wherein the at least one layer unit comprises at least one metal halide perovskite;
a control unit configured to control the information displayed on the one or more display devices;
and
at least one light generating unit configured to send generated light rays with a determined wavelength and/or intensity to at least one specific layer unit, several layer units or each layer unit of the one or more display devices.

9. The display system according claim 8, wherein the display system further comprises a light generating unit operable to generate light rays, wherein the light generating unit is configured to generate light rays of different wavelength and/or of different intensity and to send a determined intensity of generated light rays with or without a determined wavelength to one, several or each layer unit of the one or more display devices so that the quantity of light rays passing through the layer unit is changed.

10. The display system according to claim 8, wherein the control unit is additionally configured to control the wavelength and/or the intensity of the generated light rays (generated by the light generating unit to the or each layer unit of the one or more display devices.

11. A method for changing a transparency while displaying information for a driver in a vehicle, the method comprising:
sending instructions, by a control unit, to one or more display devices so that images are displayed on at least one of the one or more display devices, wherein the control unit is a control unit in a display system; and
simultaneously or sequentially displaying such images on at least one of the one or more display devices while the quantity of non-generated light rays passing through the at least one layer unit is changed.

12. The method according to claim 11, wherein changing the quantity of light rays passing through the at least one layer unit comprises sending instructions, by the control unit, to a light generating unit so that the light generating unit sends generated light rays to a specific, several or each layer unit of one or more display devices so that the quantity of non-generated light rays passing through the layer unit changes.

13. The method according to claim 11, wherein the method additionally comprises:
generating an electric current and/or voltage from the at least one layer unit when light rays pass through the at least one layer unit;
and
using the generated electric current and/or voltage, by the display unit, the light generating unit and/or the control unit.

14. A method for producing a display device and/or a display system, the method comprising:
providing or producing a display unit,
dissolving a salt comprising at least one ion of at least one metal halide perovskite;
producing a layer unit onto one surface of the display unit, by using the dissolved at least one ion of the at least one metal halide perovskite, so that a display device comprises the layer unit operable to change the quantity of light rays to pass through the layer unit which comprises the at least one metal halide perovskite;
and
providing and configuring:
a light generating unit to send generated light rays to the layer unit of the display device; and/or
a control unit to control the information displayed on the display unit of the one or more display devices.

15. The display device according to claim 2, wherein the suitable anion is methylamine, formamidine, and/or caesium.

16. The display device according to claim 2, wherein the metal having the valency of 2+ is lead, tin, or a combination thereof.

17. The display device according to claim 2, wherein the halogenide is iodide.

18. The display device according to claim 2, wherein the at least one metal halide perovskite comprises methylamine or formamidine, lead, and iodide.

19. The display device according to claim 2, wherein the x, y, z is any integer between 0 and 10.

20. The display device according to claim 2, wherein the at least one metal halide perovskite has the formula (CH₃)H₃NPbI₃ or FA2Pb₁I₄.
